(19) United States
(12) Patent Application Publication
(10) Pub. No.: US 2025/0333840 A1
(43) Pub. Date: Oct. 30, 2025

(54) METHOD OF DETERMINING END POINT OF CHAMBER CLEANING PROCESS

(71) Applicant: ASM IP Holding B.V., Almere (NL)

(72) Inventors: Marina Mariano, Leuven (BE); Kelly Houben, Lubbeek (BE); Bert Jongbloed, Oud-Heverlee (BE)

(21) Appl. No.: 19/185,832

(22) Filed: Apr. 22, 2025

Related U.S. Application Data
(60) Provisional application No. 63/638,202, filed on Apr. 24, 2024.

(51) Int. Cl. C23C 16/44; C23C 16/52; H01L 21/67

(52) U.S. Cl. CPC C23C 16/4405; C23C 16/52; H01L 21/67028; H01L 21/67253

(57) ABSTRACT

A method of determining an end point of a substrate processing chamber cleaning process is disclosed. The method comprises the steps of performing a soaking step comprising containing a cleaning gas within the substrate processing chamber and receiving at least two pressure measurements of pressure in the substrate processing chamber while the cleaning gas is contained within the chamber; and determining whether an end point of the cleaning process has been reached based on the at least two pressure values.

### CROSS-REFERENCE TO RELATED APPLICATION(S)

This Application claims the benefit of U.S. Provisional Application 63/638,202 filed on Apr. 24, 2024, the entire contents of which are incorporated herein by reference.

### FIELD OF INVENTION

The present invention relates generally to semiconductor processing and, more particularly, to cleaning processes in substrate processing apparatus.

### BACKGROUND OF THE DISCLOSURE

In a vertical furnace reactor, wafers can be batch processed by loading a number of wafers into a boat and inserting the boat into the reactor process chamber. During a deposition cycle taking place in the process chamber, such as a low pressure chemical vapor deposition (LPCVD) process to form silicon nitride, one or more layers of material are formed on the wafers. In addition, material can be deposited on the inner surface of the process chamber. As this layer accumulates, the probability of particle contamination by release of particles from the inner surfaces onto wafers in the process chamber increases. The material layer may also trap process byproducts which can be released onto the wafers, causing further contamination.

It will be appreciated that particle formation on the wafers is undesirable because the particles can detrimentally affect the performance of semiconductor devices formed on the wafers.

Material can also be deposited on inner surfaces of an injector for providing a process gas to the chamber, as well as on surfaces of components present in the chamber such as a boat, a liner, or other components. This can be a further source of particle contamination. In addition, deposition of material in and around gas exit holes of the injector can affect the flow rate of gas provided to the chamber, which can result in decreased throughput.

A cleaning process can be carried out after one or more deposition cycles have taken place, in order to remove material layers deposited on inner surfaces of the chamber and injector(s). The cleaning process can involve providing a cleaning gas to the chamber, which then reacts with the material layers to produce reaction products which can be removed from the chamber via a gas exhaust. The cleaning gas can have a deleterious effect on the material of the process chamber and injectors themselves: this is an effect which may be referred to as over-etching. Over-etching can reduce the lifetime of the process chamber and other components exposed to the cleaning gas, and so it is important to be able to stop the cleaning process at an appropriate point to minimize such damage.

Consequently, there is a need for a substrate processing systems and methods that provide accurate estimation of an end point of a cleaning process.

### SUMMARY OF THE DISCLOSURE

According to a first embodiment of the present invention there is provided a method of determining an end point of a substrate processing chamber cleaning process, the method comprising the steps of performing a soaking step comprising containing a cleaning gas within the substrate processing chamber and receiving at least two pressure measurements of pressure in the substrate processing chamber while the cleaning gas is contained within the chamber; and determining whether an end point of the cleaning process has been reached based on the at least two pressure values.

If a layer of material is present on inner surfaces of the chamber, this material may react with the cleaning gas confined in the chamber during the soaking step. As the chamber is closed to gases during the soaking step, any reaction products produced from the reaction between the cleaning gas and any material layer remaining in the chamber are not exhausted and remain in the chamber, thus causing a change in the chamber pressure. By measuring the pressure at at least two different points in time during the soak step, it can be determined if and to what extent the pressure in the chamber is changing.

It is an advantage of embodiments of the present invention that a method of end point detection is provided which relies on components generally already present in such type of apparatus, thus not requiring expensive or complicated components to be installed and maintained. It is an advantage of embodiments of the present invention that end point detection can be performed reliably and without adding substantially to the duration of the cleaning process. It is an advantage of embodiments of the present invention that a method of end point detection is provided which can be integrated smoothly into an existing cleaning process without requiring operator intervention.

According to a second aspect of the present invention there is provided a substrate processing apparatus comprising a process chamber arranged for receiving one or more substrates; a process gas flow source for providing a flow of process gas into the process chamber; a cleaning gas flow source for providing a flow of cleaning gas into the process chamber via a cleaning gas inlet; an exhaust outlet for removing a gas from the process chamber; a pressure measurement device for measuring pressure in the process chamber; and a controller configured to perform a method according to the first aspect.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

Certain embodiments of the present invention will now be described, by way of example, with reference to the accompanying drawings, in which:

FIG. 1 is a schematic representation of a substrate processing apparatus according to embodiments of the present invention;

FIG. 2 is a flow chart of a method according to embodiments of the present invention;

FIG. 3 is a plot of pressure difference as a function of number of cleaning- soaking cycles.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate. Semiconductor substrates can be processed in batches in vertical furnaces. An example of such processing is the deposition of layers of various materials on the substrates.

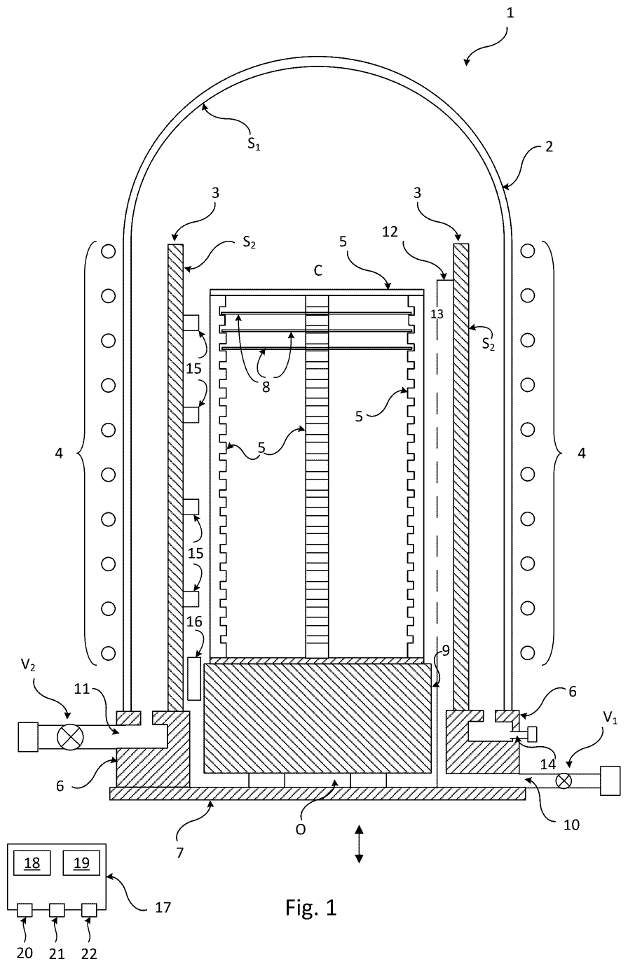

Referring to FIG. 1, a substrate processing apparatus 1 is shown in cross section. The substrate processing apparatus 1 includes a substrate processing chamber 2 which is generally bell jar shaped and a process tube or liner 3 disposed within the substrate processing chamber 2. The process tube 3 is illustrated in FIG. 1 as open ended but may in some embodiments be closed off at the upper end. The process tube or liner 3 can be considered to function as an inner reaction tube. In some embodiments, the substrate processing apparatus 1 does not comprise the liner 3. The inclusion or not of the liner 3 in the substrate processing apparatus may depend on the type of process to be carried out. For example, if a silicon nitride deposition process is to be carried out, generally a liner 3 would be provided in the substrate processing chamber 2.

The substrate processing chamber 2 may be surrounded by heating means, such as one or more thermally resistive heating coils 4 powered by an electrical power supply (not shown). The heating means provides heat to the substrate processing chamber 2 which subsequently causes the interior volume I of the substrate processing chamber 2 to be heated, including the process tube 3. Both the substrate processing chamber 2 and the liner 3 may be made of quartz, silicon carbide, silicon or another suitable heat resistant material.

In the embodiment shown in FIG. 1 the liner 3 defines a reaction space C in which a wafer boat 5 is receivable. If the liner 3 is not provided, the reaction space C in which a wafer boat is receivable is defined by the interior space of the substrate processing chamber 2. Both the substrate processing chamber 2 and the liner 3 may be supported at their lower end on a flange 6 for partially closing an open end of the liner 3. The flange may be made of stainless steel. The wafer boat 5 may enter and/or exit the reaction space C via a central furnace opening O provided in the flange 6. A vertically movably arranged door 7 may be configured to close off the opening O in the flange 6 and may be configured to support the wafer boat 5. The wafer boat 5 is configured to support wafers 8. The wafer boat 5 may sometimes be inserted into the chamber while empty i.e. not supporting any wafers 8. The wafers 8 may in some cases be dummy wafers which are not intended to be used for further manufacture.

The door 7 may be provided with a pedestal 9. The pedestal 9 may be rotated to have the wafer boat 5 in the inner space rotating. Under the lowest wafer in the boat 5 a flow space may be provided to prevent the flow of reaction gas between the wafers 8 in the boat.

The substrate processing apparatus 1 comprises at least one gas flow inlet 10 for providing a flow of gas into the substrate processing chamber 2. The inlet 10 may be comprised in the flange 6.

A gas flow control valve V₁ is provided in fluid connection with the gas flow inlet 10 for controlling gas flow through the gas flow inlet 10. The flange 6 comprises a gas exhaust outlet 11 to remove gas from the inner space. The gas exhaust outlet may be connected to a vacuum pump (not shown). An exhaust control valve V₂ is provided in fluid connection with the gas exhaust outlet 11 for controlling gas flow through the gas exhaust outlet 11.

The gas flow inlet 10 may be configured to provide a flow of one or more of a process gas, a purge gas, and a cleaning gas into the substrate processing chamber 2. In some embodiments, separate gas flow inlets may be provided for each of a process gas and a cleaning gas and optionally a purge gas. In some embodiments, the gas flow inlet 10 may be configured to provide a flow of a process gas and a cleaning gas into the substrate processing chamber 2. By flowing a cleaning gas through the same gas flow path as a process gas, deposits of material on interior surfaces of the process gas flow path can be removed. The gas flow inlet 10 may be connected to a gas flow line which is connected to one or more of a process gas source, a purge gas source, and a cleaning gas source and the gas which is flowed through the gas flow inlet 10 may be controlled by opening/closing appropriate valves in the gas flow line.

The gas inlet 10 may be provided with an injector 12 constructed and arranged within the assembly to extend vertically into the inner space I along the substantial cylindrical wall of the liner 3 (or along the wall of the substrate processing chamber 1 if no liner is provided) towards the higher end and comprising injector openings 13 to inject gas in the reaction space C. In some embodiments, the injector 12 is not provided and the gas flows upwards from the inlet 10 into the reaction space C without its flow being directed by an injector 12. In some embodiments, a gas flow inlet 10 provided with an injector 12 may be provided in addition to a gas flow inlet which is not connected to an injector, allowing gas to flow upwards from the inlet 10 into the reaction space C without its flow being directed by an injector. One, three or more gas flow inlets 10 may be provided, each capable of conducting one or more of cleaning, process, and purge gas.

In some embodiments, the assembly may be provided with a purge gas inlet 14 mounted on the flange for providing a purge gas to the reaction space C. The purge gas inlet 14 may optionally be provided with a purge gas injector (not shown) extending vertically along the outer surface of the cylindrical wall of the liner 2 (or along the wall of the substrate processing chamber 1 if no liner is provided) from the flange 3 towards the top end of the liner. In some embodiments, the purge gas injector is not provided and the purge gas flows upwards from the purge gas inlet 14 into the reaction space C without its flow being directed by a purge gas injector. In some embodiments, the purge gas inlet 14 is not provided and purge gas may be flowed into the reaction space C through the gas inlet 10.

One or more thermocouples 15 may be provided within the substrate processing chamber 2 for measuring the temperature inside the substrate processing chamber 2. This temperature is referred to herein as the substrate processing chamber temperature. The thermocouples 15 may be provided each within a different heating zone of the chamber C corresponding to a respective heating element 4.

The substrate processing apparatus 1 comprises a pressure measurement device 16 which is located inside the substrate processing chamber 2 and is configured to measure a pressure in the substrate processing chamber 2. The pressure measurement device 16 may be, for example, a capacitance manometer.

By way of example, a typical deposition cycle carried out by the substrate processing apparatus 1 may proceed as follows. The door 7 is moved downwards and a wafer boat 5 containing wafers 8 to be processed is placed on the pedestal. The door 7 is moved upwards and positioned such that the substrate processing chamber 2 is closed on the lower end. A series of temperature changes (for example by controlling power provided to the heating elements 4), process gas flows for forming layers of material on the wafers 8, and purge gas flows for removing excess process gas and formed reaction by-products, is carried out depending on the desired wafer characteristics. In one embodiment, the deposition cycle is a process for depositing silicon nitride on the wafers 8, for example using dichlorosilane and ammonia as precursors or hexachlorodisilane and ammonia. The skilled person will understand that other deposition processes are possible in the substrate processing apparatus 1. At the end of a deposition cycle the temperature is returned to a standby temperature and the wafer boat 5 is removed from substrate processing chamber 2 via the opening O.

In addition to forming layers of material on the wafers 8, the process gas may form a material layer on surfaces within the substrate processing chamber 2 which are exposed to the process gas, for example the inner surface S₁ of the substrate processing chamber 2; the surface S₂ of the liner 3 (if present); inner and outer surfaces of the injector 12; the surfaces of the boat 5 and the pedestal 9. This material layer is a source of particle contamination. The material layer thickness present can vary for different inner surfaces or components, for example depending on their process gas exposure. For example, the process gas pressure within the injector 12 during a deposition cycle may be significantly higher than the process gas pressure within the substrate processing chamber 2 during the same deposition cycle, and therefore the material layer thickness deposited on an inner surface of the injector 12 may be greater than that deposited on an inner surface of the substrate processing chamber 2.

After one or more deposition cycles have taken place, a cleaning process may be carried out which comprises flowing a cleaning gas through the substrate processing chamber 2. Before carrying out the cleaning process, the boat 5 is removed from the substrate processing chamber 2. The boat 5 may be emptied of wafers 8 and returned to the substrate processing chamber 2 before the cleaning process is started, so that the boat 5 may be exposed to cleaning gas without exposing wafers 8 to cleaning gas. The cleaning gas comprises a gas which is capable of reacting with the material layer deposited on surfaces within the substrate processing chamber 2 by the process gas. By way of example but not limitation, the material layer may comprise one or more of silicon nitride, silicon, titanium nitride, molybdenum. The cleaning gas may comprise fluorine. The cleaning gas may comprise a dilution component such as nitrogen, helium, neon, argon, or other inert gas. The cleaning gas may comprise nitrogen trifluoride (NF3). The cleaning gas may comprise chlorine trifluoride (ClF3).

When the cleaning gas reacts with the material layer, the reaction products are released into the atmosphere of the substrate processing chamber 2 i.e. are not attached to the inner surfaces of the substrate processing chamber 2 or components contained therein and can be removed from the substrate processing chamber 2 via the exhaust outlet 11. Once a surface is free of the material layer, further exposure of the surface may result in etching of the surface itself, which can cause damage to the surface or component and decrease its lifetime. Therefore, ending the cleaning process before the components/surfaces of the substrate processing apparatus 1 are damaged, or before a maximum damage limit has been reached, can be important in maintaining the lifetime of the apparatus 1. The end point of a particular cleaning process may be chosen, for example, to be a point at which the material layer on the inner surface of the substrate processing chamber 2 has been fully removed while a material layer may remain on other components or surfaces such as the injector. The end point may be chosen, for example, to be a point at which a particular fraction of a material layer on the inner surface of the substrate processing chamber 2 has been removed. The end point may be chosen, for example, to be a point at which no material layer remains on any component or surface in the substrate processing chamber 2, as over-etching may be allowable if particle contamination is to be reduced to the greatest extent possible.

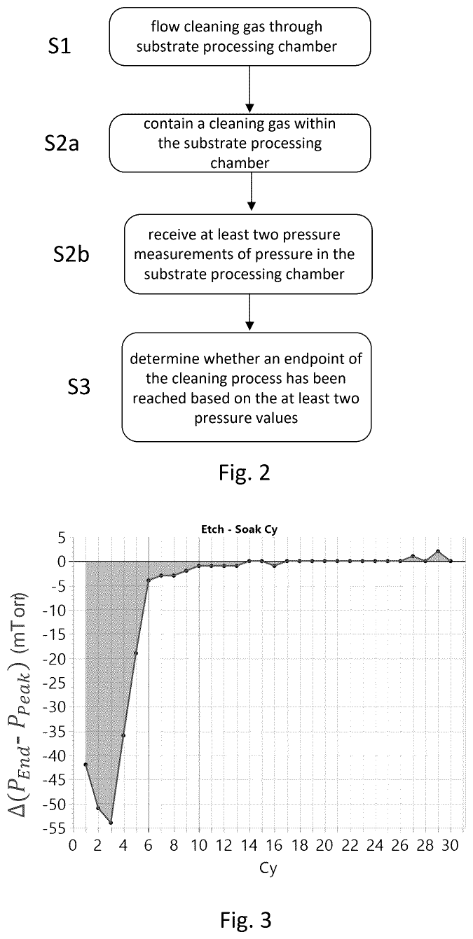

Embodiments of the present invention provide a method of determining an end point of a substrate processing chamber cleaning process. After the end point, no further cleaning steps are carried out before a subsequent deposition cycle is carried out. Referring to FIG. 2, the method comprises the steps of: performing a cleaning step comprising flowing a cleaning gas through the substrate processing chamber (step S1); performing a soaking step after the cleaning step, the soaking step comprising containing a cleaning gas within the substrate processing chamber (step S2a) and measuring at least two pressure values in the substrate processing chamber while the cleaning gas is contained in the substrate processing chamber (step S2b); and determining whether an end point has been reached based on the at least two pressure values (step S3). As will be described in more detail hereinafter, in some embodiments, step S1 may be omitted.

In step S1, a cleaning gas is flowed through the substrate processing chamber 2. The flow of gas may be implemented by causing the gas flow control valve V₁ to be opened and causing a cleaning gas to be flowed through the gas flow inlet 10, while at the same time causing the exhaust valve V₂ to be opened such that the cleaning gas can flow into the substrate processing chamber 2, react with any material layer deposited on surfaces and/or components in the substrate processing chamber 2, generating reaction products, which reaction products may then flow out of the substrate processing chamber 2 via the exhaust outlet 11. The pressure in the substrate processing chamber 2 during the cleaning step of S1 may be controlled to be less than atmospheric pressure. The pressure may be controlled for example by use of a pressure control valve (not shown) located upstream of the gas flow inlet 10. Step S1 may comprise setting the temperature in the substrate processing chamber 2 to a cleaning step temperature value, which may be chosen so as to optimize cleaning conditions.

In step S2a, a cleaning gas is contained in the substrate processing chamber 2 so as to perform a soak. The cleaning gas may be contained in the substrate processing chamber 2 by closing the exhaust valve V₂ and the gas flow control valve V₁. The gas flow control valve V₁ may be closed at the same time as the exhaust valve V₂ is closed, such that the cleaning gas which is present in the substrate processing chamber 2 at the moment of closing both valves remains in the substrate processing chamber 2. The gas flow control valve V₁ may be closed slightly after the exhaust valve V₂ is closed, so as to allow additional cleaning gas to flow into the substrate processing chamber 2 before the substrate processing chamber 2 is sealed by closing the gas flow control valve V₁. The cleaning gas is confined in the substrate processing chamber 2 for a predetermined time interval. At the end of the soaking step, the exhaust valve V₂ and the gas flow control valve V₁ are opened again.

In step S2b, which is part of the soaking step, at least two pressure values in the substrate processing chamber 2 are measured while the cleaning gas is contained within the substrate processing chamber 2. The pressure values are each measured at a different point in time. For example, a starting pressure value P₁ may be measured as soon as the substrate processing chamber 2 is sealed, i.e. once both the exhaust valve V₂ and the gas flow control valve V₁ are closed, or soon thereafter. An end pressure value P₂ may be measured a predetermined time after the starting pressure value P₁ is measured, for example just before or shortly before the end of the soaking step.

In step S3, it is determined whether an end point has been reached based on the at least two pressure values. If any material layer is present in the substrate processing chamber 2 during the soaking step, this material layer may react with the cleaning gas and produce reaction products. As the gas inlet and gas exhaust are closed off, the reaction products cannot escape the chamber, thus a change in the pressure inside the substrate processing chamber 2 can be observed. For example, the reaction of silicon nitride with fluorine proceeds as follows: Si₃N₄+6F₂→3SiF₄+2N₂. For every six moles of fluorine gas, 5 moles of gas are produced as reaction products. Thus the pressure in the substrate processing chamber 2 decreases as a result of the reaction taking place. The amount of material layer remaining can affect the magnitude and rate of the pressure change.

The at least two pressure values thus allow determination of whether an end point of the cleaning process has been reached. For example, the difference in the two pressure values may be compared with a threshold value and if the difference is less than the threshold value, it may be determined that the end point of the cleaning process has been reached. If the difference is greater than the threshold value, it may be determined that the end point has not been reached and another cleaning step may be performed, which may be a soak step as described in more detail hereinafter. The rate of change of pressure may be determined from the difference in pressure values and the difference in the time at which the pressure measurements were made and the rate of change of pressure may be compared to a threshold value to determine whether the end point of the cleaning process has been reached.

In some embodiments, multiple pressure values may be measured and two or more pressure values may be selected from the multiple pressure values in order to determine whether the end point has been reached. For example, a maximum pressure value may be selected from the multiple pressure values and may be subtracted from a pressure value measured at or close to the end of the soak step and the difference may be compared with a threshold value to determine whether the end point has been reached.

In some embodiments, three or more pressure values may be measured and a function may be fitted to the three or more pressure values. For example, an exponential function may be fitted to the three or more pressure values. One or more parameters of the function can be used to determine whether an end point has been reached. For example, a decay rate of the pressure over time may be compared with a threshold value in order to determine whether the end point has been reached.

Threshold values for determining whether an end point has been reached may be experimentally determined values, for example determined by repeatedly performing the cleaning step and the soaking step (or repeatedly performing the soaking step only, or carrying out one soaking step of a longer duration) and obtaining a set of pressure values for each soaking step (or for the duration of a single long soaking step) until no change in the pressure behaviour is observed for repeated application of cleaning and soaking steps (or repeated application of a single soaking step, or for the duration of a single long soaking step), at which point it may be assumed that no material layer remains in the interior of the substrate processing chamber 2 or its components. This can provide a set of calibration values which can be matched to a particular cleaned state of the substrate processing chamber 2 and its components. For example, the pressure difference in the substrate processing chamber may be related to the partial pressure of the cleaning gas. The partial pressure of the cleaning gas may be related to the consumption of the material layer and therefore to the amount of cleaning which has been carried out.

If it is determined that the end point of the cleaning process has not been reached, steps S1-S3 may be repeated. In this way the progress of the cleaning process can be monitored and the cleaning process can be halted once a desired condition of the inner surfaces/components of the substrate processing chamber 2 has been reached.

Referring once more to FIG. 1, the substrate processing apparatus 1 comprises a controller 17 which is configured to perform a method according to embodiments of the present invention as described herein. The controller 17 may be implemented in hardware or in software. The controller 17 may be (physically) part of a central control module (not shown) or may be (physically) separate from and in communication with a central control module (not shown). The controller 17 may comprise a memory 18 configured to store instructions for performing a method according to embodiments of the present invention. The memory 18 may store one or more threshold values representing an end point of one or more cleaning processes. The controller 17 may comprise a processor 19 which may be configured for processing data such as pressure measurements. The controller 17 may comprise one or more inputs 20 for receiving data such as pressure data directly or indirectly from a pressure measurement device. The controller 17 may comprise one or more inputs 21 for receiving data, signals, and/or instructions from other control modules comprised in the substrate processing apparatus 1, for example a central control module, a gas control module, a temperature control module (not shown). The controller 17 may comprise one or more outputs 22 for providing data, signals, and/or instructions to other control modules comprised in the substrate processing apparatus 1, for example a central control module, a gas control module, a temperature control module (not shown).

The controller 17 may be configured to control a state of the gas flow control valve V₁ and of the exhaust control valve V₂. The state of a valve may be binary, that is, the valve may be either open or closed. The state of a valve may be the degree to which the valve is open or closed and thus may take one of a range of values. The controller 17 may be configured to control the state directly, for example by providing an electrical signal to a control input of a valve V₁ or V₂. The controller 17 may be configured to control the state indirectly, for example by providing a signal to a valve control module (not shown) which is configured to receive signals from the controller 17 and to control the valves V₁ and V₂ according to information contained in signals received from the controller 17.

The controller 17 may be configured to cause the gas flow control valve V₁ to be opened, thereby causing a cleaning gas to be flowed through the gas flow inlet 10, while at the same time causing the exhaust valve V₂ to be opened such that the cleaning gas can flow into the substrate processing chamber 2, thereby causing the cleaning step of step S1 to be carried out.

The controller 17 may be configured to cause the gas flow control valve V₁ to be opened, thereby causing a cleaning gas to be flowed through the gas flow inlet 10, while at the same time causing the exhaust valve V₂ to be opened such that the cleaning gas can flow into the substrate processing chamber 2, thereby causing the cleaning step of step S1 to be carried out.

The controller 17 may be configured to cause the gas flow control valve V₁ to be opened, thereby causing a cleaning gas to be flowed through the gas flow inlet 10, while at the same time causing the exhaust valve V₂ to be closed such that the cleaning gas can flow into the substrate processing chamber 2 so as to allow the substrate processing chamber 2 to be filled with an amount of cleaning gas.

The controller 17 may be configured to cause the gas flow control valve V₁ to be closed while at the same time causing the exhaust valve V₂ to be closed such that a cleaning gas is confined in the substrate processing chamber 2, thereby causing the soaking step of step S2a to be carried out. The controller 17 may be configured to cause the gas flow control valve V₁ to be closed slightly after causing the exhaust valve V₂ to be closed, thereby allowing more cleaning gas to flow into the substrate processing chamber 2 before the gas flow control valve V₁ is closed. This can allow the pressure of the cleaning gas in the substrate processing chamber 2 during the soaking step to be adjusted. For example, in some embodiments (described in more detail hereinafter) the cleaning step S1 is not performed and the controller 17 is configured to implement a soaking step at a pressure sufficient to cause a reaction between the cleaning gas and a material layer deposited on an inner surface of the substrate processing apparatus by allowing a time duration between closing the exhaust valve V₂ and closing the gas flow control valve V₁.

The controller 17 is configured to receive pressure measurements from the pressure measurement device 15, thereby carrying out step S2b. The controller 17 may receive such pressure measurements directly, for example the controller 17 may be operably connected to the pressure measurement device 15 such that pressure measurement data are provided directly from the pressure measurement device 15 to the controller 17. The controller 17 may receive pressure measurements indirectly, for example the pressure measurement device 15 may comprise or be coupled to a pressure measurement device controller (not shown) which is configured to receive pressure measurement data from the pressure measurement device sensor, optionally to process the received pressure measurement data, and to provide pressure measurement data to the controller 17.

The controller 17 is configured to determine whether an end point of the cleaning process has been reached based on the at least two pressure measurements. For example, the controller 17 may be configured to, in the processor 19, retrieve a threshold value from the memory 18, calculate the difference between two of the at least two pressure measurements, and compare the difference with the threshold value. The controller 17 may be configured to implement steps S1 to S3 again if it is determined that the end point has not been reached. The controller may be configured to implement steps S2 and S3 again if it is determined that the end point has not been reached.

As an illustrative (non-limiting) example, referring to FIG. 3, a temperature control method according to embodiments of the present invention was carried out in a system according to embodiments of the present invention, commercially available under the trade name Sonora™ from ASM International N.V. of Almere, The Netherlands. A series of silicon nitride deposition cycles were carried out on silicon wafers. The wafer boat was then removed from the substrate processing chamber, the wafers were transferred from the boat to wafer storage, and the boat was returned to the substrate processing chamber. A cleaning step was performed followed by a soak step according to embodiments of the present invention, and these steps were repeated 30 times. The pressure in the substrate processing chamber was measured during each soak step and the difference between the maximum chamber pressure and the chamber pressure at the end of each soak step was calculated. Referring to FIG. 3, it can be seen that this pressure difference decreases over time as more cleaning steps are performed. After 6 cleaning cycles the majority of the material layer is removed.

In some embodiments, the cleaning step S1 may not be implemented and the soaking step may be used as a cleaning process. As described hereinbefore, reaction of the cleaning gas with the material layer during the soaking step causes part of the material layer to be removed from inner surfaces of the substrate processing chamber and components contained therein. By choosing the pressure of the cleaning gas in the substrate processing chamber during the soaking step, the amount of cleaning gas provided may be sufficient to provide a cleaning effect during the soaking step. This may be particularly advantageous if a thin layer of material is present e.g. less than 5 nm, as the cleaning step SI may be omitted and the time for the cleaning process and end point detection may be reduced compared to a process in which the cleaning step and the soaking step are performed. The pressure measurements may be acquired and used to determine an end point of the cleaning process as described hereinbefore. If it is determined that the end point of the cleaning process has not been reached, the soaking step may be repeated. Alternatively, a cleaning step S1 may be performed followed by a soaking step as described hereinbefore.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

The methods according to embodiments of the present invention are not limited to application in a vertical furnace or batch processing apparatus and can equally be implemented in a single wafer or minibatch reactor.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments. The subject matter of the present disclosure includes all novel and nonobvious combinations and subcombinations of the various processes, systems, and configurations, and other features, functions, acts, and/or properties disclosed herein, as well as any and all equivalents thereof.

1. A method of determining an end point of a substrate processing chamber cleaning process, the method comprising:
performing a soaking step comprising containing a cleaning gas within a substrate processing chamber and receiving at least two pressure measurements of pressure in the substrate processing chamber while the cleaning gas is contained within the substrate processing chamber; and
determining whether an end point of the substrate processing chamber cleaning process has been reached based on the at least two pressure measurements.

2. The method of claim 1, comprising performing a cleaning step before the soaking step.

3. The method of claim 2, comprising performing a cleaning step comprising flowing a cleaning gas through the substrate processing chamber before performing the soaking step.

4. The method of claim 1, wherein the soaking step is also a cleaning step.

5. The method of claim 1, wherein the soaking step comprises closing a chamber gas exhaust outlet, flowing a cleaning gas into the substrate processing chamber, and closing a substrate processing chamber cleaning gas inlet, thereby containing the cleaning gas in the substrate processing chamber.

6. The method of claim 1, wherein the substrate processing chamber pressure at the beginning of the soaking step is less than atmospheric pressure.

7. The method of claim 1, wherein determining whether the end point has been reached comprises comparing a difference in two pressure values separated in time with a threshold value.

8. The method of claim 1, wherein at least three temporally separated pressure values are measured during the soaking step and wherein determining whether the end point has been reached comprises comparing a rate of change of substrate processing chamber pressure during the soaking step with a threshold value, wherein the rate of change is determined using the at least three temporally separated pressure values.

9. The method of claim 7, wherein the threshold value is a value which corresponds to a state in which a deposited material layer on an internal surface of the substrate processing chamber has been substantially removed.

10. The method of claim 7, wherein the substrate processing chamber is comprised in a substrate processing apparatus, the substrate processing apparatus comprising a process gas injector for providing a process gas to the substrate processing chamber, wherein the threshold value is a value which corresponds to a state in which a deposited material layer on an internal surface of the process gas injector has been substantially removed.

11. A substrate processing method comprising:
providing one or more substrates in a substrate processing chamber;
providing one or more precursor gases in the substrate processing chamber such that a layer is deposited on the one or more substrates and on an interior surface of the substrate processing chamber; and
performing a method of determining an end point of a substrate processing chamber cleaning process comprising:
performing a soaking step comprising containing a cleaning gas within the substrate processing chamber and receiving at least two pressure measurements of pressure in the substrate processing chamber while the cleaning gas is contained within the substrate processing chamber; and
determining whether an end point of the substrate processing chamber cleaning process has been reached based on the at least two pressure measurements.

12. A substrate processing apparatus comprising:
a process chamber arranged for receiving one or more substrates;
a process gas flow source for providing a flow of process gas into the process chamber;
a cleaning gas flow source for providing a flow of cleaning gas into the process chamber via a cleaning gas inlet;
an exhaust outlet for removing a gas from the process chamber;
a pressure measurement device for measuring pressure in the process chamber; and
a controller configured to perform a method of determining an end point of a cleaning process:
perform a soaking step comprising containing a cleaning gas within the process chamber and receive at least two pressure measurements of pressure in the process chamber while the cleaning gas is contained within the process chamber; and
determine whether an end point of the cleaning process has been reached based on the at least two pressure measurements.

13. The substrate processing apparatus of claim 12, wherein the controller is configured to perform the following steps:
i) implement a soak step by setting the cleaning gas inlet to an open state and thereby causing a cleaning gas to be flowed into the substrate processing chamber; setting the exhaust outlet to a closed state and setting the cleaning gas inlet to a closed state, thereby causing a cleaning gas to be contained in the substrate processing chamber; and waiting for a soak period; and receiving at least two pressure values from the pressure measurement device during the soak period; and
ii) determine whether an end point of chamber cleaning has been reached based on the at least two pressure values.

14. The substrate processing apparatus according to claim 13, wherein the controller is configured to implement a cleaning step before the soaking step by setting the cleaning gas inlet to an open state and setting the exhaust outlet to an open state and causing a cleaning gas to be flowed through the chamber.

15. The substrate processing apparatus according to claim 14 wherein in the soaking step the controller is configured to wait a predetermined period between causing the exhaust outlet to close and causing the cleaning gas inlet to close, thereby causing the chamber to be filled with a quantity of cleaning gas such that the pressure in the chamber at the start of the soak period is less than atmospheric pressure.

16. The substrate processing apparatus according to claim 14 wherein in the soaking step the controller is configured to wait a predetermined period between causing the exhaust outlet to close and causing the cleaning gas inlet to close, thereby causing the chamber to be filled with a quantity of cleaning gas such that the pressure in the chamber at the start of the soak period is sufficient to cause a reaction between the cleaning gas and a material layer deposited on an inner surface of the substrate processing apparatus.

17. The substrate processing apparatus according to claim 13 wherein the controller is configured to, as part of step iii), compare a difference in two pressure values separated in time with a threshold value.

18. The substrate processing apparatus according to claim 17, wherein the controller is configured to receive at least three pressure values during the soaking step and to determine whether the end point has been reached by comparing a variation in rate of change of chamber pressure during the soaking step with a threshold value.

19. The substrate processing apparatus according to claim 18, wherein the threshold value is a value which corresponds to a state in which a deposited material layer on an internal surface of the chamber has been substantially removed.

20. The substrate processing apparatus according to claim 18, wherein the process gas flow source comprises a process gas injector for providing a process gas to the chamber, wherein the threshold value is a value which corresponds to a state in which a deposited material layer on an internal surface of the process gas injector has been substantially removed.
